(19) United States
(12) Patent Application Publication
(10) Pub. No.: US 2023/0231548 A1
(43) Pub. Date: Jul. 20, 2023

(54) DIGITAL ISOLATOR AND DIGITAL SIGNAL TRANSMISSION METHOD THEREOF

(71) Applicant: Silergy Semiconductor Technology (Hangzhou) LTD, Hangzhou (CN)

(72) Inventors: Yufei Dong, Hangzhou (CN); Xiaodong Huang, Hangzhou (CN); Chen Zhao, Hangzhou (CN)

(21) Appl. No.: 18/097,563

(22) Filed: Jan. 17, 2023

(30) Foreign Application Priority Data
Jan. 19, 2022 (CN) 202210061073.6

(51) Int. Cl. H03K 7/10; H04L 25/06; H04L 25/49

(52) U.S. Cl. CPC H03K 7/10; H04L 25/069; H04L 25/4902

(57) ABSTRACT

A digital isolator can include: an encoding circuit configured to receive an input digital signal, and to encode a rising edge and a falling edge of the input digital signal into different encoded signals; an isolating element coupled to the encoding circuit, and being configured to transmit the encoded signal in an electrical isolation manner; and a decoding circuit configured to receive the encoded signal through the isolating element, and to decode the encoded signal to obtain the rising edge and the falling edge, in order to output an output digital signal consistent with the input digital signal.

### RELATED APPLICATIONS

This application claims the benefit of Chinese Patent Application No. 202210061073.6, filed on Jan. 19, 2022, which is incorporated herein by reference in its entirety.

### FIELD OF THE INVENTION

The present invention generally relates to the field of power electronics, and more particularly to digital isolators and associated digital signal transmission methods.

### BACKGROUND

In an electronic system, a digital isolator is a device that has a high resistance isolation characteristic when a digital signal and an analog signal are transmitted, in order to realize isolation between an electronic system and the user. Circuit designers typically introduce isolation to meet safety requirements, or to reduce the noise of the grounding loop. Current isolation can ensure that data transmission is not through electrical connection or a leakage path, thereby avoiding security risks.

### BRIEF DESCRIPTION OF THE DRAWINGS

FIG. 1 is a schematic block diagram of a digital isolator, in accordance with embodiments of the present invention.

FIG. 2 is a waveform diagram of example operation of a digital isolator.

FIG. 3 is a waveform diagram of first example operation of a digital isolator, in accordance with embodiments of the present invention.

FIG. 4 is a waveform diagram of second example operation of a digital isolator, in accordance with embodiments of the present invention.

FIG. 5 is a waveform diagram of third example operation of a digital isolator, in accordance with embodiments of the present invention.

FIG. 6 is a waveform diagram of fourth example operation of a digital isolator, in accordance with embodiments of the present invention.

FIG. 7 a waveform diagram of fifth example operation of a digital isolator, in accordance with embodiments of the present invention.

FIG. 8 a waveform diagram of sixth example operation of a digital isolator, in accordance with embodiments of the present invention.

FIG. 9 is a schematic block diagram of seventh example operation of a digital isolator, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

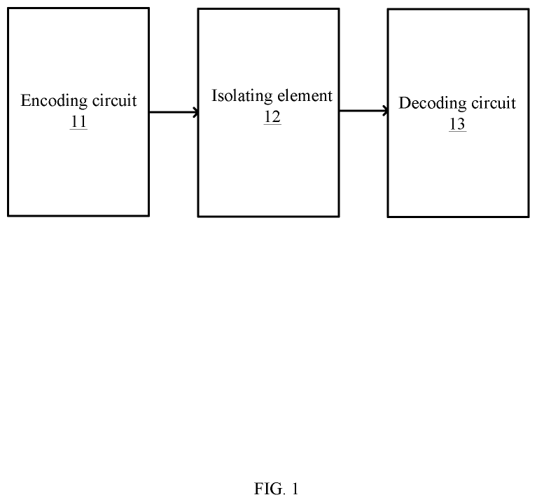

Referring now to FIG. 1, shown is a schematic block diagram of a digital isolator, in accordance with embodiments of the present invention. In this particular example, digital isolator 1 can include encoding circuit 11, isolating element 12, and decoding circuit 13. Encoding circuit 11 can connect to decoding circuit 13 through isolating element 12, in order to realize the transmission of the input digital signal as input to the output terminal of the digital isolator by electrical isolation. Encoding circuit 11 may receive an input digital signal, and can encode a rising edge and a falling edge of the input digital signal into different encoded signals. Isolating element 12 can be a capacitor or a transformer for transmitting the encoded signal in an electrical isolation manner. Decoding circuit 13 can connect to isolating element 12, and may receive the encoded signal to decode to obtain the rising edge and the falling edge, in order to obtain an output digital signal that is consistent with (e.g., the same as) the input digital signal. In this way, encoding and transmission of the input digital signal may be realized.

In particular embodiments, encoding circuit 11 may begin to output encoded signals after the rising or falling edges of input digital signal DIN are detected, and can encode the rising edge of input digital signal DIN as a first pulse sequence, and the falling edge of input digital signal DIN as a second pulse sequence. The first pulse sequence can include a plurality of first pulse groups, and the second pulse sequence can include a plurality of second pulse groups. The first and second pulse groups may differ in at least one of the number, interval time, amplitude, width, polarity, and/or arrangement of pulses.

Decoding circuit 13 may output the rising edge by counting the number of first pulse groups to a first predetermined value that is less than the number of first pulse groups, and/or output the falling edge by counting the number of second pulse groups to a second predetermined value that is less than the number of second pulse groups. The first and second pulse groups may each include at least one pulse, which can be either a single pulse or a pulse sequence composed of multiple continuous pulses. Thus, by forming a pulse group according to a predetermined way, and then arranging a plurality of pulse groups to form a corresponding pulse sequence, and characterizing the rising edge and falling edge of the input digital signal respectively through different pulse sequences, the encoded signal simultaneously can include pulse information, pulse group information, and pulse sequence information, such that the amount of information is more abundant. Further, because the number of pulse groups required for decoding is less than the number of pulse groups for encoding, redundant encoded signals can be allowed to be misjudged during the determination of the rising edge and falling edge, thereby improving the anti-interference ability of the encoded signal.

Because the two pulse sequences are different, isolating element 12 (e.g., a capacitor, a transformer, etc.) can transmit pulse sequences (the encoded signal) in electrical isolation (e.g., the input and output terminals of the digital isolator are not grounded) to decoding circuit 13. Decoding circuit 3 may output a rising edge transition after detecting the first pulse sequence, and may output a falling edge transition after detecting the second pulse sequence. Further, the rising edge can be output after detecting a predetermined number of the first pulse groups, and the falling edge may be output after detecting a predetermined number of the second pulse groups. In particular embodiments, encoding circuit 11 and decoding circuit 13 can be formed by an edge detection circuit, a signal modulator, and a carrier generator. The output of encoding circuit 11 can be a single pulse signal or a dual differential signal, whereby a dual differential signal can further enhance the anti-interference ability. In addition, when a single pulse signal is used as the encoded signal, one isolating element can be used. When the dual differential signal is used as encoded signal(s), two isolating elements may be utilized.

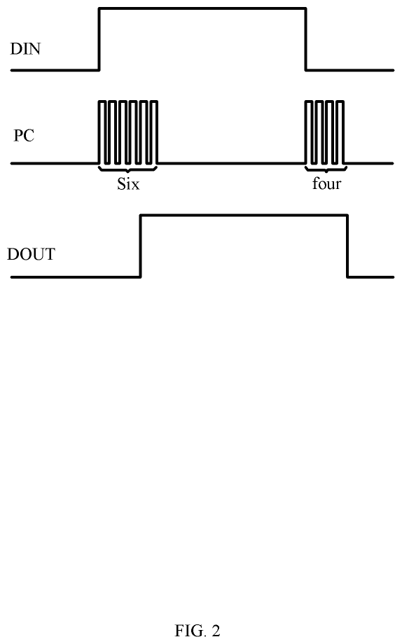

Referring now to FIG. 2, shown is a waveform diagram of example operation of a digital isolator. In this particular example, in the digital isolator, the rising edge may correspond to 6 consecutive pulses, and the falling edge may correspond to 4 consecutive pulses. Therefore, at the decoding end, the rising edge and the falling edge can be identified by counting the number of continuous pulses in a predetermined period, and digital signal DOUT may output. However, the digital isolator using this encoding method may have relatively poor anti-interference ability in some cases. If electromagnetic interference occurs during transmission, possibly resulting in a change in the number of continuous pulses, this may lead to decoding errors at the decoder in such cases.

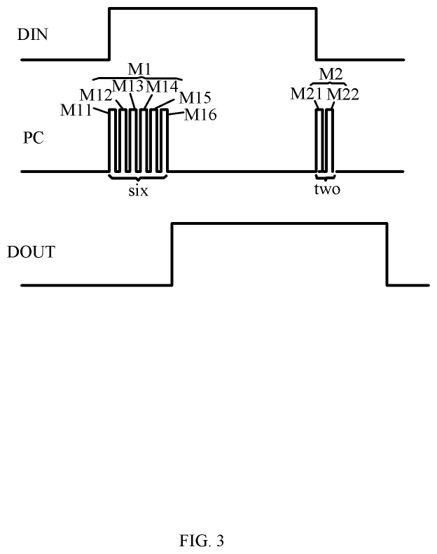

Referring now to FIG. 3, shown is a waveform diagram of first example operation of a digital isolator, in accordance with embodiments of the present invention. In this particular example, pulse sequence M1 corresponding to the rising edge of input digital signal DIN can include 6 first pulse groups (e.g., M11-M16), each of which can include one pulse. Pulse sequence M2 corresponding to the falling edge of input digital signal DIN can include 2 second pulse groups (e.g., M21 and M22), each of which can include one pulse. In this example, the number of the first pulse groups in pulse sequence M1 may be different from the number of the second pulse group in pulse sequence M2. Therefore, e.g., decoding circuit 3 can output the rising edge by counting the number of the first pulse groups to be not less than 4 first pulse groups, such as 4, 5 or 6, and output the falling edge by counting the number of the second pulse groups to be less than 4 second pulse groups, such as 1, 2, or 3, instead of outputting the rising edge by identifying 6 first pulse groups, and outputting the falling edge by identifying two second pulse groups. Thus, using the digital isolator of particular embodiments, even if electromagnetic interference occurs during the transmission process, resulting in a change in the number of continuous pulses, redundant pulses can also be misjudged, thereby improving the anti-interference ability of the encoded signal.

In this example, the output signal of the encoding circuit can be encoded as signal PC. The decoding circuit may receive encoded signal PC through the isolating element, and can output the rising edge at the output terminal after detecting pulse sequence M1 in encoded signal PC, and the falling edge at the output terminal after detecting pulse sequence M2 in encoded signal PC. It should be understood that the number and type of the first and second pulse groups can be set according to particular requirements. If the setting is increasingly complex, the complexity of the circuit can correspondingly increase, and the anti-interference performance may be further improved.

Pulse sequence M1 can include multiple identical first pulse groups, and pulse sequence M2 can include multiple identical second pulse groups. For example, each first pulse group in the first pulse sequence can also take the same form as each second pulse group in the second pulse sequence. When the first pulse group adopts the same form, the second pulse group may adopt the same form, and the first and second pulse groups adopt the same form, the number, polarity, width, amplitude, and arrangement of pulses in the first and second pulse groups can be the same. Thus, the output of the encoded signal, and the detection of the rising and falling edges can be facilitated by setting the same pulse group.

Furthermore, the setting method of the pulse sequence in this example may improve the anti-interference performance. By setting the same form of the first pulse group and the same form of the second pulse group, this may facilitate reduction of the delay time of signal transmission, and improve the overall performance of the digital isolator. For example, when the first pulse sequence includes several identical first pulse groups and the second pulse sequence includes several identical second pulse groups, the first and second pulse groups may take the same form, or different forms. When the first and second pulse groups adopt different forms, the first and second pulse groups may differ in at least one of the number, width, polarity, time interval, amplitude, and/or arrangement of pulses.

In this example, the first pulse sequence can include multiple different first pulse groups, and the second pulse sequence can include multiple different second pulse groups. Among them, “multiple different” may represent the existence of at least two different first pulse groups or second pulse groups. When there are different first pulse groups or second pulse groups, the pulses in each first pulse group can be different in at least one of the number, width, polarity, time interval, amplitude, and/or arrangement, and the pulses in each second pulse group may be different in at least one of the number, width, polarity, time interval, amplitude, and/or arrangement.

Particular embodiments can encode the rising edge and falling edge of the input digital signal into the first pulse sequence and the second pulse sequence respectively through the encoding circuit. The first pulse sequence can include a plurality of first pulse groups, and the second pulse sequence can include a plurality of second pulse groups. The decoding circuit may output the rising edge by counting the number of first pulse groups to a first predetermined value that is less than the number of first pulse groups, and/or may output the falling edge by counting the number of the second pulse groups to a second predetermined value that is less than the number of the second pulse groups. Therefore, the redundant encoded signal can be allowed to be misjudged when the rising and falling edges are judged. In addition, the encoded information corresponding to the rising and falling edges can be accurately transmitted through the isolation element, and encoding and transmission of the input digital signal can be realized.

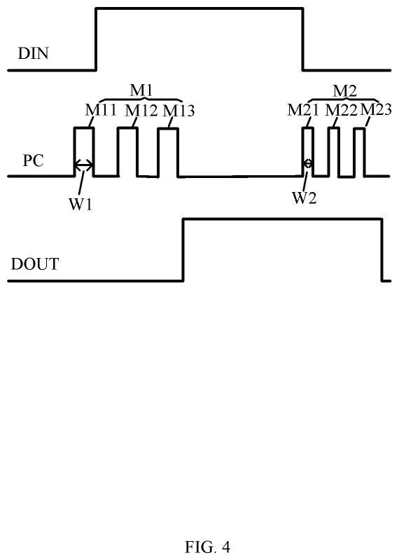

Referring now to FIG. 4, shown is a waveform diagram of second example operation of a digital isolator, in accordance with embodiments of the present invention. In this particular example, pulse sequence M1 corresponding to the rising edge of the input digital signal can include three first pulse groups (e.g., M11-M13), whereby each of which can include one pulse. The width of the pulse in first pulse groups M11-M13 is W1. Pulse sequence M2 corresponding to the falling edge of and input digital signal DIN can include three second pulse groups (e.g., M21-M23), whereby each of which can include a single pulse. The width of the pulse in second pulse groups M21-M23 is W2. In this example, the number of the first pulse group in pulse sequence M1 is the same as the number of the second pulse group in pulse sequence M2, and the width of the pulse is different. Therefore, decoding circuit 3 can output the rising edge by counting 2 or 1 first pulse group(s) with width W1, and output the falling edge by counting 2 or 1 second pulse group(s) with width W2, instead of outputting the rising edge by identifying 3 first pulse groups, and outputting the falling edge by identifying 3 second pulse groups. Thus, using the digital isolator of particular embodiments, even if electromagnetic interference occurs during the transmission process, resulting in a change in the number of continuous pulses, redundant pulses can also be misjudged, thereby improving the anti-interference ability of the encoded signal.

It should be understood that the number and type of the first and second pulse groups can be set according to particular needs, and the first and second pulse groups can be set more complex, such that the complexity of the circuit will increase and the anti-interference performance is further improved. Further, the first pulse sequence can include multiple different first pulse groups, and the second pulse sequence can include multiple different second pulse groups. When the first pulse sequence includes multiple identical first pulse groups, and the second pulse sequence includes multiple second pulse groups with the same number of first pulse groups, the first and second pulse groups may differ in at least one of the pulse width, polarity, amplitude, and/or arrangement.

In this example, the first pulse sequence can include multiple different first pulse groups, and the second pulse sequence can include multiple different second pulse groups. Among them, “multiple different” may represent the existence of at least two different first pulse groups or second pulse groups. When there are different first pulse groups or second pulse groups, the pulses in each first pulse group can be different in at least one of the number, width, polarity, time interval, amplitude, and/or arrangement, and the pulses in each second pulse group are different in at least one of the number, width, polarity, time interval, amplitude, and/or arrangement.

Particular embodiments can encode the rising edge and falling edge of the input digital signal into the first pulse sequence and the second pulse sequence respectively through the encoding circuit. The first pulse sequence can include a plurality of first pulse groups, and the second pulse sequence can include a plurality of second pulse groups. The decoding circuit may outputs the rising edge by counting the number of first pulse groups to a first predetermined value that is less than the number of first pulse groups, and/or output the falling edge by counting the number of the second pulse group to a second predetermined value that is less than the number of the second pulse group. Therefore, the redundant encoded signal can be allowed to be misjudged when the rising and falling edges are judged. Therefore, encoded information corresponding to the rising and falling edges can be accurately transmitted through the isolating element, and encoding and transmission of the input digital signal can be realized.

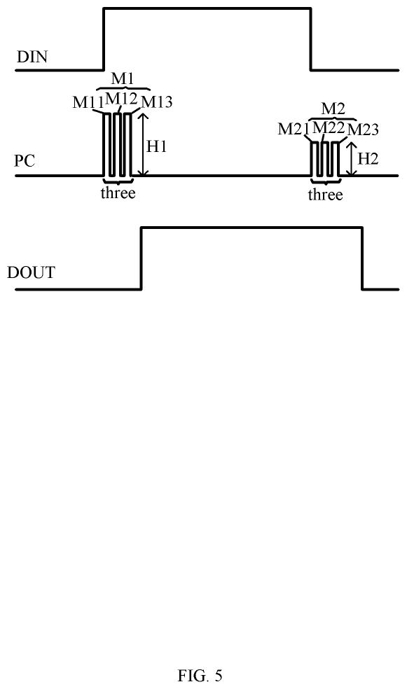

Referring now to FIG. 5, shown is a waveform diagram of third example operation of a digital isolator, in accordance with embodiments of the present invention. Pulse sequence M1 corresponding to the rising edge of input digital signal DIN can include three first pulse groups (e.g., M11-M13), whereby each of which can include one single pulse. The amplitude of the pulse in first pulse groups M11-M13 is H1. Pulse sequence M2 corresponding to the falling edge of input digital signal DIN can include three second pulse groups (e.g., M21-M23), whereby each of which can include a single pulse. The amplitude of the pulse in second pulse groups M21-M23 is H2. In this example, the number of the first pulse group in pulse sequence M1 is the same as the number of the second pulse group in pulse sequence M2, and the amplitude of the pulse is different. Therefore, decoding circuit 3 can output the rising edge by counting 2 or 1 first pulse group with amplitude H1, and output the falling edge by counting two or one second pulse group with amplitude H2, instead of counting three first pulse groups to output the rising edge and counting three second pulse groups to output the falling edge. Thus, using the digital isolator of particular embodiments, even if electromagnetic interference occurs during the transmission process, resulting in a change in the number of continuous pulses, redundant pulses can also be misjudged, thereby improving the anti-interference ability of the encoded signal.

Particular embodiments may encode the rising edge and falling edge of the input digital signal into the first pulse sequence and the second pulse sequence respectively through the encoding circuit. The first pulse sequence can include a plurality of first pulse groups, and the second pulse sequence can include a plurality of second pulse groups. The decoding circuit may output the rising edge by counting the number of first pulse groups to a first predetermined value that is less than the number of first pulse groups, and/or output the falling edge by counting the number of the second pulse group to a second predetermined value that is less than the number of the second pulse group. Therefore, the redundant encoded signal can be allowed to be misjudged when the rising and falling edges are judged. Accordingly, the encoded information corresponding to the rising and falling edges can be accurately transmitted through the isolation element, and encoding and transmission of the input digital signal can be realized.

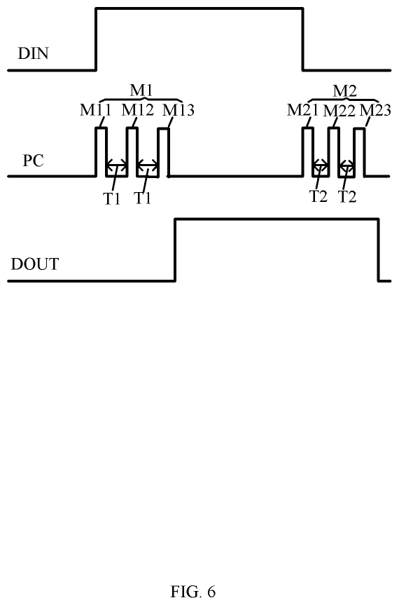

Referring now to FIG. 6, shown is a waveform diagram of fourth example operation of a digital isolator, in accordance with embodiments of the present invention. Pulse sequence M1 corresponding to the rising edge of input digital signal DIN can include three first pulse groups (e.g., M11-M13), whereby each of which can include one single pulse. The time interval between two adjacent first pulse groups is T1. Pulse sequence M2 corresponding to the falling edge of input digital signal DIN can include three second pulse groups (e.g., M21-M23), whereby each of which can include a single pulse. The time interval between two adjacent second pulse groups is T2. In this example, the number of the first pulse groups in pulse sequence M1 is the same as that in pulse sequence M2, and the time interval of the first pulse groups is different from that of the second pulse groups. Therefore, decoding circuit 13 can output the rising edge by counting two or one first pulse groups with time interval T1, and output the falling edge by counting two or one second pulse group with time interval T2, instead of counting three first pulse groups to output the rising edge, and counting three second pulse groups to output the falling edge. Thus, using the digital isolator of particular embodiments, even if electromagnetic interference occurs during the transmission process, resulting in a change in the number of continuous pulses, redundant pulses can also be misjudged, thereby improving the anti-interference ability of the encoded signal.

Particular embodiments can encode the rising edge and falling edge of the input digital signal into the first and second pulse sequences respectively through the encoding circuit. The first pulse sequence can include a plurality of first pulse groups, and the second pulse sequence can include a plurality of second pulse groups. The decoding circuit may output the rising edge by counting the number of first pulse groups to a first predetermined value that is less than the number of first pulse groups, and/or output the falling edge by counting the number of the second pulse group to a second predetermined value that is less than the number of the second pulse groups. Therefore, the redundant encoded signal can be allowed to be misjudged when the rising and falling edges are judged. Accordingly, the encoded information corresponding to the rising and falling edges can be accurately transmitted through the isolating element, and encoding and transmission of the input digital signal can be realized.

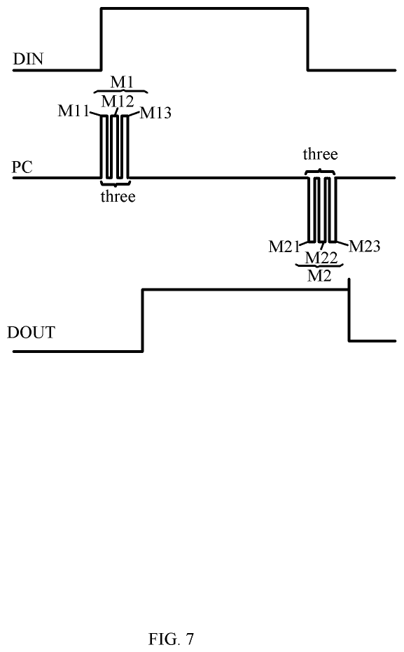

Referring now to FIG. 7, shown is a waveform diagram of fifth example operation of a digital isolator, in accordance with embodiments of the present invention. In this particular example, pulse sequence M1 corresponding to the rising edge of input digital signal DIN can include three first pulse groups (e.g., M11-M13), whereby each of which can include one pulse. The pulses in first pulse groups M11-M13 are positive pulses. Pulse sequence M2 corresponding to the falling edge of input digital signal DIN can include three second pulse groups (e.g., M21-M23), whereby each of which can include a pulse. The pulses in second pulse groups M21-M23 are negative pulses. In this particular example, the number of the first pulse groups in pulse sequence M1 is the same as the number of the second pulse groups in pulse sequence M2, and the polarity of the pulses is different. Therefore, decoding circuit 3 can output the rising edge by counting two or one positive first pulse groups, and may output the falling edge by counting two or one negative second pulse groups, instead of counting three first pulse groups to output the rising edge, and counting three second pulse groups to output the falling edge. Thus, using the digital isolator of particular embodiments, even if electromagnetic interference occurs during the transmission process, resulting in a change in the number of continuous pulses, redundant pulses can also be misjudged, thereby improving the anti-interference ability of the encoded signal.

Particular embodiments can encode the rising edge and falling edge of the input digital signal into first and second pulse sequences respectively through the encoding circuit. The first pulse sequence can include a plurality of first pulse groups, and the second pulse sequence can include a plurality of second pulse groups. The decoding circuit can output the rising edge by counting the number of first pulse groups to a first predetermined value that is less than the number of first pulse groups, and/or may output the falling edge by counting the number of the second pulse group to a second predetermined value that is less than the number of the second pulse group. Therefore, the redundant encoded signal can be allowed to be misjudged when the rising and falling edges are judged. Accordingly, the encoded information corresponding to the rising and falling edges can be accurately transmitted through the isolation element, and encoding and transmission of the input digital signal can be realized.

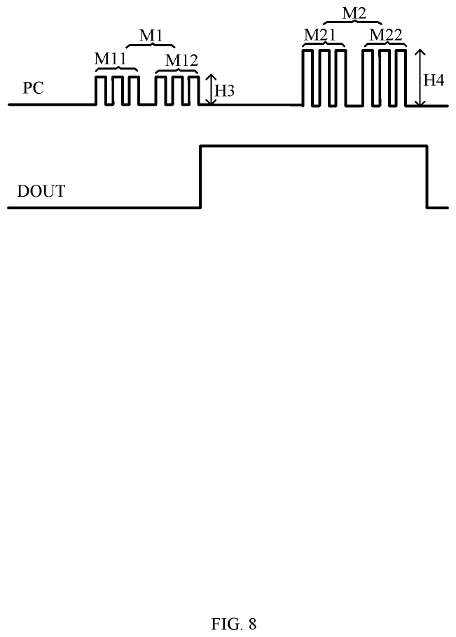

Referring now to FIG. 8, shown is a waveform diagram of sixth example operation of a digital isolator, in accordance with embodiments of the present invention. In this particular example, pulse sequence M1 corresponding to the rising edge of input digital signal DIN can include two first pulse groups (e.g., M11 and M12). The amplitude of the pulse in first pulse groups M11 and M12 is H3. First pulse groups M11 and M12 may adopt the same form of pulse sequence, including three pulses, and the polarity, width, amplitude, and/or arrangement of each pulse can be the same. Pulse sequence M2 corresponding to the falling edge of input digital signal DIN can include two second pulse groups (e.g., M21 and M22). The amplitude of the pulses in second pulse groups M21 and M22 is H4.

Second pulse groups M21 and M22 may adopt the same form of pulse sequence, including three pulses, and the polarity, width, amplitude, and/or arrangement of each pulse can be the same. Further, the pulses in first pulse group M11 and the second pulse group M21 can be different in amplitude, but the width and polarity of the pulse may be the same. Therefore, decoding circuit 3 can output the rising edge by counting one first pulse group with amplitude H3, and may output the falling edge by counting one second pulse group with amplitude H4, instead of counting two first pulse groups to output the rising edge, counting two second pulse groups to output the falling edge. Thus, using the digital isolator of particular embodiments, even if electromagnetic interference occurs during the transmission process, resulting in a change in the number of continuous pulses, redundant pulses can also be misjudged, thereby improving the anti-interference ability of the encoded signal.

Particular embodiments can encode the rising edge and falling edge of the input digital signal into the first and second pulse sequences respectively through the encoding circuit. The first pulse sequence can include a plurality of first pulse groups, and the second pulse sequence can include a plurality of second pulse groups. The decoding circuit can output the rising edge by counting the number of first pulse groups to a first predetermined value that is less than the number of first pulse groups, and/or may output the falling edge by counting the number of the second pulse groups to a second predetermined value that is less than the number of the second pulse groups. Therefore, the redundant encoded signal can be allowed to be misjudged when the rising and falling edges are judged. Therefore, the encoded information corresponding to the rising and falling edges can be accurately transmitted through the isolation element, and encoding and transmission of the input digital signal can be realized.

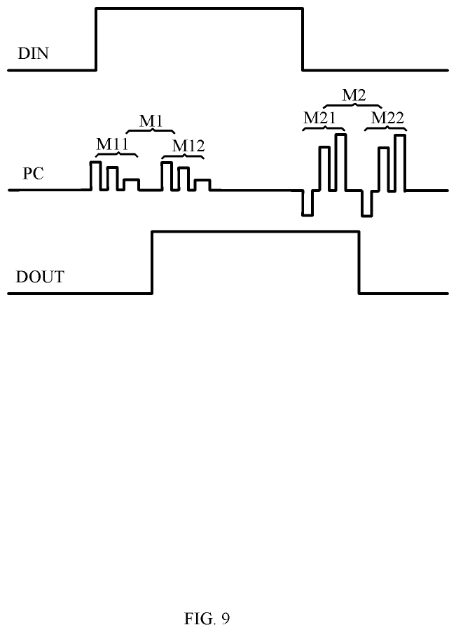

Referring now to FIG. 9, shown is a waveform diagram of seventh example operation of a digital isolator, in accordance with embodiments of the present invention. In this particular example, pulse sequence M1 corresponding to the rising edge of input digital signal DIN can include two identical first pulse groups (e.g., M11 and M12). The three pulses in the first pulse group M11 may have the same pulse polarity but different amplitudes, and the width of the last pulse in first pulse group M11 can also be different from the previous two pulses. In addition, pulse sequence M2 corresponding to the falling edge of input digital signal DIN can include two identical second pulse groups (e.g., M21 and M22). Both second pulse groups can include three different pulses. The three pulses in second pulse group M21 may have the same width but different amplitudes. Moreover, the first pulse in second pulse group M21 is a negative pulse, and the last two pulses are positive pulses. That is, the polarity of the pulses in second pulse group M21 is different.

Thus, through the above settings, the amount of information in the encoded signal is more abundant, thereby improving the anti-interference ability of the encoded signal. Further, decoding circuit 13 can decode to output the rising edge by identifying first pulse group M11, and to output the falling edge by identifying second pulse group M21. It may not be necessary to identify two first pulse groups to decode the output rising edge, and to output the falling edge by identifying two second pulse groups. Thus, using the digital isolator of particular embodiments, even if electromagnetic interference occurs during the transmission process, resulting in a change in the number of continuous pulses, redundant pulses can also be misjudged, thereby improving the anti-interference ability of the encoded signal.

Particular embodiments can encode the rising edge and falling edge of the input digital signal into the first pulse sequence and the second pulse sequence respectively through the encoding circuit. The first pulse sequence can include a plurality of first pulse groups, and the second pulse sequence can include a plurality of second pulse groups. The decoding circuit can output the rising edge by counting the number of first pulse groups to a first predetermined value that is less than the number of first pulse groups, and/or may output the falling edge by counting the number of the second pulse groups to a second predetermined value that is less than the number of the second pulse groups. Therefore, the redundant encoded signal can be allowed to be misjudged when the rising and falling edges are judged. Accordingly, the encoded information corresponding to the rising and falling edges can be accurately transmitted through the isolating element, and encoding and transmission of the input digital signal can be realized.

An example digital signal transmission method may also be provided in certain embodiments, and can be applied to the digital isolator. For example input digital signal can be received by an encoding circuit. The rising edge and falling edge of the input digital signal can respectively be encoded into different encoded signals. In this example, the rising edge and falling edge of the input digital signal can be encoded by a encoding circuit. The encoding circuit can include an edge detection circuit, a signal modulator, and a carrier generator. The encoding circuit may encode the rising edge and the falling edge of the input digital signal into different encoded signals, and the encoded signal can be generated after the rising edge or the falling edge is detected. The encoding circuit may output a single pulse signal or a double differential signal as the encoded signal.

In this example, the rising edge can be encoded as a first pulse sequence, and the falling edge encoded as a second pulse sequence. The first pulse sequence can include multiple first pulse groups, the second pulse sequence can include multiple second pulse groups, and the first and second pulse groups can each include at least one pulse. The rising edge may be decoded to output by counting the number of the first pulse group to a first predetermined value that is less than the number of the first pulse group, and/or the falling edge can be decoded to output by counting the number of the second pulse group to a second predetermined value that is less than the number of the second pulse group. Further, the setting method of the first pulse sequence and the second pulse sequence may adopt any of the above pulse sequence setting methods.

The encoded signal can be transmitted by electrical isolation. For example, the encoded signal can be transmitted by electrical isolation through the isolating element (e.g., a capacitor or a micro transformer). When the encoding circuit outputs a single pulse signal, a single-ended transmission isolating element may be utilized. When the encoding circuit outputs a dual differential signal, a differential transmission isolating element can be utilized to further improve the anti-interference ability of the pulse sequence transmission process and the anti-interference performance of the digital isolator. The encoded signal can be received and decoded to output the rising and falling edges, in order to obtain an output digital signal that is consistent with the input digital signal.

In this example, a decoding circuit may receive the encoded signal to output the rising and falling edges. The decoding circuit can include an edge detection circuit, a signal modulator, and a carrier generator. Further, the decoding circuit may receive the encoded signal and decode to output the rising and falling edges. The rising edge can be controlled to output after receiving the first pulse sequence, and the falling edge may be controlled to output after receiving the second pulse sequence. Further, the rising edge can be output after receiving a predetermined number of the first pulse groups, and the falling edge may be output after receiving a predetermined number of the second pulse groups.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A digital isolator, comprising:
a) an encoding circuit configured to receive an input digital signal, and to encode a rising edge and a falling edge of the input digital signal into different encoded signals;
b) an isolating element coupled to the encoding circuit, and being configured to transmit the encoded signal in an electrical isolation manner;
c) a decoding circuit configured to receive the encoded signal through the isolating element, and to decode the encoded signal to obtain the rising edge and the falling edge, in order to output an output digital signal consistent with the input digital signal;
d) wherein the rising edge of the input digital signal is encoded as a first pulse sequence, and the falling edge of the input digital signal is encoded as a second pulse sequence;
e) wherein the first pulse sequence comprises a plurality of first pulse groups, and the second pulse sequence comprises a plurality of second pulse groups, and each of the first pulse sequence and the second pulse sequence comprises at least one pulse; and
f) wherein the decoding circuit is configured to output the rising edge by counting the number of the first pulse groups to a first predetermined value that is less than the number of the first pulse groups, and/or to output the falling edge by counting the number of the second pulse groups to a second predetermined value that is less than the number of the second pulse groups.

2. The digital isolator of claim 1, wherein:
a) the encoding circuit is configured to output the encoded signal after detecting the rising edge and the falling edge; and
b) the decoding circuit is configured to output the rising edge after detecting the first pulse sequence and to output the falling edge after detecting the second pulse sequence.

3. The digital isolator of claim 1, wherein the first pulse sequence comprises multiple identical first pulse groups, and the second pulse sequence comprises multiple identical second pulse groups.

4. The digital isolator of claim 1, wherein the first and second pulse groups differ in at least one of a number, a width, a polarity, a time interval, an amplitude, and an arrangement of pulses.

5. The digital isolator of claim 1, wherein the number of the first pulse groups in the first pulse sequence is different from the number of the second pulse groups in the second pulse sequence.

6. The digital isolator of claim 5, wherein:
a) the first pulse sequence comprises M first pulse groups;
b) the second pulse sequence comprises N second pulse groups;
c) the decoding circuit is configured to output the rising edge by counting the number of the first pulse groups to be not less than P, and to output the falling edge by counting the number of the second pulse groups to be less than P; and
d) M, N, P are all positive integers, and P is between M and N.

7. The digital isolator of claim 1, wherein the number of the first pulse groups in the first pulse sequence is the same as that of the second pulse groups in second pulse sequence, and the first and second pulse groups are different in at least one of an interval time, an amplitude, a width, a polarity, and an arrangement of pulses.

8. The digital isolator of claim 7, wherein the decoding circuit is configured to output the rising edge by counting the number of the first pulse groups to be the first predetermined value, and to output the falling edge by counting the number of the second pulse groups to be the second predetermined value.

9. The digital isolator of claim 1, wherein the first pulse group comprises a plurality of identical pulses, and the second pulse group comprises a plurality of identical pulses.

10. The digital isolator of claim 1, wherein each of the first and second pulse groups comprises a single pulse.

11. A method of digital signal transmission, method comprising:
a) receiving an input digital signal;
b) encoding a rising edge and a falling edge of the input digital signal into different encoded signals, respectively;
c) transmitting the encoded signal in an electrical isolation manner;
d) receiving the encoded signal and decoding the encoded signal to obtain the rising edge and the falling edge, in order to output an output digital signal consistent with the input digital signal;
e) wherein the rising edge of the input digital signal is encoded as a first pulse sequence, and the falling edge of the input digital signal is encoded as a second pulse sequence;
f) wherein the first pulse sequence comprises a plurality of first pulse groups, and the second pulse sequence comprises a plurality of second pulse groups, and the first pulse sequence and the second pulse sequence comprises at least one pulse; and
g) wherein the decoding circuit is configured to output the rising edge by counting the number of first pulse groups to a first predetermined value that is less than the number of first pulse groups, and/or to output the falling edge by counting the number of second pulse groups to a second predetermined value that is less than the number of second pulse groups.

12. The method of claim 11, wherein the rising edge is controlled to output after detecting the first pulse sequence, and the falling edge is controlled to output after detecting the second pulse sequence.

13. The method of claim 11, wherein the first pulse sequence comprises multiple identical first pulse groups, and the second pulse sequence comprises multiple identical second pulse groups.

14. The method of claim 11, wherein the first and second pulse groups differ in at least one of a number, a width, a polarity, a time interval, an amplitude, and an arrangement of pulses.

15. The method of claim 11, wherein the first pulse group comprises a plurality of identical pulses, and the second pulse group comprises a plurality of identical pulses.
